(19) United States
(12) Patent Application Publication
(10) Pub. No.: US 2014/0268553 A1
(43) Pub. Date: Sep. 18, 2014

(54) SYSTEM FOR COOLING MULTIPLE IN-LINE CENTRAL PROCESSING UNITS IN A CONFINED ENCLOSURE

(71) Applicant: Silicon Graphics International Corp., Fremont, CA (US)

(72) Inventors: Kevin Lee Van Pelt, Longmont, CO (US); Theodore Robert Johnson, Louisville, CO (US); Robert Michael Kinstle III, Livermore, CA (US)

(21) Appl. No.: 13/931,781

(22) Filed: Jun. 28, 2013

Related U.S. Application Data
(60) Provisional application No. 61/786,416, filed on Mar. 15, 2013.

(51) Int. Cl. H05K 7/20

(52) U.S. Cl. CPC H05K 7/20809; H05K 7/20709
USPC 361/679.52; 361/679.54

(57) ABSTRACT

A system for cooling multiple in-line CPUs in a confined enclosure is provided. In an embodiment, the system may include a front CPU and a front heat sink that may be coupled to the front CPU. The front heat sink may have a plurality of fins and a corresponding fin pitch. The system may further include a rear CPU disposed in line with the front CPU and a rear heat sink coupled to the rear CPU. The rear heat sink may have a plurality of fins and a corresponding fin pitch. The fin pitch of the rear heat sink may be higher than the fin pitch of the front heat sink. In another embodiment, the front and rear heat sinks may be coupled together by one or more heat pipes.

### CROSS-REFERENCE TO RELATED APPLICATIONS

The present application claims the priority benefit of U.S. provisional application No. 61/786,416, titled “SYSTEM FOR COOLING MULTIPLE IN-LINE CENTRAL PROCESSING UNITS IN A CONFINED ENCLOSURE,” filed Mar. 15, 2013, the disclosure of which is incorporated herein by reference.

### BACKGROUND

1. Field of the Invention

The present invention relates to cooling central processing units (CPUs). More specifically, the present invention relates to a system for cooling multiple in-line CPUs in a confined enclosure such as a sever tray or server blade.

2. Description of the Related Art

Modern CPUs are becoming increasingly powerful at a rapid rate. As CPU technologies progress, manufacturers are also continuously condensing these more powerful CPUs into smaller form factors. As a result, modern CPUs achieve high power densities in which they can exercise significant computing power without occupying significant space within computer enclosures (e.g., personal computer enclosures, server trays, or server blades). Placing this increased power within confined enclosure spaces, however, results in increased enclosure temperatures as the CPUs generate heat with limited space to dissipate it or otherwise divert it away from the CPUs.

When enclosure temperatures get too high, modern CPUs automatically lower their performance to prevent damage to their electronics. In doing so, the CPUs are forced to sacrifice overall system performance. To avoid having to make such a counterproductive sacrifice, CPUs depend on cooling systems that mitigate these temperature-related concerns. Common cooling systems include the use of heat sinks in combination with either air or liquid cooling. Air cooling systems utilize an air flow that is typically directed through the server enclosure by one or more fans located at or near the front of the server. In some cases, the air flow is produced by a central air conditioning system.

Some modern CPUs, especially those employed in high-powered server systems, utilize nearly 135 watts of power—power than generates heat as a byproduct. Effectively cooling higher wattage CPUs in multi-CPU systems is particularly difficult, especially when enclosure space is limited or when the CPUs are aligned within the air flow. For example, in 1 U or 2 U dual-CPU servers in which the CPUs are linearly aligned within the incoming air flow, the rear CPU can easily get 20-30 degrees Centigrade hotter than the front CPU, in such systems, the rear CPU gets hotter than the front CPU because the front CPU physically blocks much of the air flow that would otherwise cool the rear CPU.

Moreover, by the time the air flow reaches the rear CPU, it has already picked up heat from the heat sink of the front CPU. The problem is further compounded in server designs that place the CPUs downstream from storage media such as hard disk drives. Where multiple hard disk drives operate upstream from the CPUs, even the air hitting the front CPU has already been pre-heated by up to 20 degrees Centigrade as a result of having drawn heat off of the drives. Because the reliability of a computer is a non-linear function of the internal enclosure temperature, having one CPU running significantly hotter than other CPUs reduces overall system reliability. As a result, the temperature of the rear CPU constitutes the primary limiting factor in overall system performance.

Previously attempted solutions for cooling high-wattage, multi-CPU servers require active cooling mechanisms. Such mechanisms require a heat-sink-mounted fan that requires additional power and monitoring efforts, more space for taller or larger heat sinks, or space for a remote cooler. Some solutions have involved tying multiple CPUs together under one large heat sink, but they are difficult to use and ultimately limit CPU placement. Another previously attempted solution involves utilizing a less efficient heat sink on the front CPU so that it transfers a less heat into the air flow path. This solution is ineffective, however, because it causes a significant rise in the temperature of the front heat sink and CPU while only sparing the rear CPU from a miniscule amount of heat exposure.

Other proffered solutions have involved connecting the CPUs to external radiators via heat pipes. These solutions do not work in confined enclosures because there is no room for the external radiator. Liquid cooling is technically effective because it does not rely on air flow for cooling, but it is neither spatially nor economically efficient. Rather, liquid cooling systems are significantly more expensive and difficult to implement than air cooling. For example, liquid cooling requires the use of an external radiator, external pump to move the liquid, and plumbing components—all of which increase cost, space consumption, and potential failure points in the overall system.

These previous solutions place a myriad of negative constraints on the overall design of servers in particular either by requiring supplemental equipment, which is uneconomical, sacrifices valuable enclosure space, and required additional power and monitoring, or by requiring that the enclosure itself be made larger, which sacrifices valuable space within the server racks and enclosures in which server trays and server blades are commonly stored. In short, there is a need in the art for cooling multiple in-line CPUs in a confined enclosure such as server tray and server blade.

### SUMMARY

The cooling system of the present invention provides for improved overall system performance and reliability in computer systems employing multiple in-line CPUs in a confined enclosure. The present invention does so primarily by reducing the amount of air flow that would otherwise be physically blocked by the heat sink of the front CPU as it travels to and contacts the heat sink of the rear CPU by using a more open or shorter design heat sink on the front CPU and a more dense or taller heat sink on the rear (downwind) CPU. Unlike previously attempted cooling solutions, the system does not require the use of an external radiator or fan. As a result, it provides the cost-effectiveness of traditional air cooling systems (as opposed to expensive liquid cooling systems), it may be used in confined enclosures that have insufficient space to house supplemental cooling devices, it frees up precious enclosure space in which additional CPUs and other components can be packed, and it increases system reliability by keeping potential failure points to a minimum. In an embodiment, a front heat sink coupled to a front CPU has a higher fin pitch than the fin pitch of a rear heat sink coupled to an in-line rear CPU. In another embodiment, the front heat sink and rear heat sink are coupled together by one or more heat pipes. In such embodiments, the system can better equalize temperatures between the two CPUs, lowering the temperature of the downstream CPU by raising the temperature of the front CPU. The net effect ultimately improves overall system performance and reliability by lowering the temperature of the hottest CPU and increasing the ambient temperature in which the system can operate without throttling the CPUs.

### BRIEF DESCRIPTION OF DRAWINGS

FIG. 1A is a top view of an exemplary system for cooling multiple in-line CPUs with a radiator in a confined enclosure in accordance with the present invention.

FIG. 1B is a top view of an exemplary system for cooling multiple in-line CPUs without a radiator in a confined enclosure in accordance with the present invention.

FIG. 2 is a side view of another exemplary system for cooling multiple in-line CPUs in a confined enclosure in accordance with the present invention.

### DETAILED DESCRIPTION

A system for cooling multiple in-line CPUs in a confined enclosure is provided. The cooling system of the present invention provides for improved overall system performance and reliability in computer systems employing multiple in-line CPUs in a confined enclosure such as a server tray or server blade. The system does so primarily by better equalizing the temperature of the leading CPU and the trailing CPU, reducing the temperatures on the trailing CPU. This is accomplished by reducing the amount of air flow that would otherwise be physically blocked by the heat sink of the front CPU as the air flow travels towards the heat sink of the rear CPU. It can also be achieved by physically connecting the two (or more) heat sinks with flexible heat pipes or the two approaches can be combined. The system provides the cost-effectiveness of traditional air cooling systems (as opposed to expensive liquid cooling systems) without requiring the use of an external radiator or fan. Because the system does not require the use of an external radiator or fan, it may be used in confined enclosures that have insufficient space to house cooling devices. Accordingly, the system also frees up precious enclosure space in which additional CPUs and other components can be packed. It also increases system reliability by keeping potential failure points to a minimum.

FIG. 1A is a top view of an exemplary system for cooling multiple in-line CPUs with a radiator in a confined enclosure in accordance with the present invention. In an embodiment, a system 100 for cooling multiple in-line CPUs in a confined enclosure 110 may include a rear CPU 120 and a rear heat sink 130 coupled to rear CPU 120. Rear heat sink 130 may have a plurality of fins 140 and a corresponding fin pitch. Fins 140 of front heat sink 130 may protrude from front heat sink 130 to provide added surface area through which front heat sink 130 may contact an air flow 150 to dissipate heat. Air flow 150 may be directed through system 100 by an external fan placed near the front of enclosure 110. In some embodiments, air flow 150 may be produced by a central air conditioning system. System 100 may further include a front CPU 160 disposed substantially in line with rear CPU 120 and a front heat sink 170 coupled to front CPU 160. Like rear heat sink 130, front heat sink 170 may include a plurality of fins 180 and a corresponding fin pitch. Fins 180 of front heat sink 170 may protrude from front heat sink 170 to provide additional surface area through which air flow 150 may contact rear heat sink 170 and dissipate heat contained within the same.

Either rear heat sink 130 or front heat sink 170 may be a standard aluminum heat sink, a vapor chamber heat sink, a forged heat sink, a swaged heat sink, a skived heat sink, an extruded heat sink, a stamped heat sink, a bonded fin heat sink, a folded fin heat sink, or any other heat sink known in the art. Either rear heat sink 130 or front heat sink 170 may be constructed of aluminum, copper, gold, silver, or any other thermally conductive material known in the art. Rear CPU 120 and front CPU 160 may be selected based on design considerations, such as enclosure size, available power supplies, and the number and type of components with which the CPUs need to communicate. In one embodiment, either rear CPU 120 or front CPU 160 may be selected from the Intel® Xeon® processor E5-2600 product family offered by Intel Corporation of Santa Clara, Calif., such as the Intel® Xeon® E5-2670 or E5-2790 processors.

In an embodiment, the fin pitch of rear heat sink 130 may be higher than the fin pitch of front heat sink 170. Fin pitch is a measurement of the distance between the fins on a heat sink. Accordingly, fin pitch factors in both fin thickness and fin quantity. For example, a heat sink having a few thick fins could have the same fin pitch as a heat sink having numerous thin fins. In embodiments of the present invention, because front heat sink 170 uses a lower fin pitch or shorter fins than rear heat sink 130, front heat sink 170 allows more of air flow 150 to pass through fins 180 and ultimately reach rear heat sink 130. In such cases, the increased air flow 150 that reaches fins 140 of rear heat sink 130 ultimately carries additional heat away from rear CPU 160. The system may be tuned to determine optimum heat sink types and fin pitches. For example, in one embodiment, front heat sink 170 may a copper vapor chamber heat sink that includes between thirty and thirty-five fins 140, while rear heat sink 130 may be a copper vapor chamber heat sink that includes between forty-five and fifty fins 180. In other embodiments, standard aluminum heat sinks may be used. In various embodiments, the optimal quantity and thickness (i.e., fin pitch) of fins 140 and 180 will depend on a number of design variables, including overall server design, enclosure size, and air flow conditions.

Although system 100 increases the temperature of front CPU 160 by forcing front CPU 160 to utilize less of air flow 150 for its own cooling purposes, system 100 significantly reduces the temperature of rear CPU 120. For example, in one embodiment, the temperature of the rear CPU 120 may be reduced as much as 10 degrees Centigrade. In doing so, system 100 effectively equalizes the temperatures between front CPU 160 and rear CPU 120. Accordingly, the cooling system of the present invention increases overall system performance and reliability.

Although system 100 may include a radiator 190 in some embodiments, system 100 need not utilize such a radiator. Because system 100 does not require the use of an external radiator, front CPU 160, front heat sink 170, rear CPU 120, and rear heat sink 130 may be enclosed in an enclosure that has insufficient space to house a radiator or other additional cooling components. This particular feature of the present invention provides a significant advantage over previously attempted cooling systems that are too expensive, too bulky, or too ineffective to adequately cool rear CPU 120 in systems using multiple in-line CPUs within confined enclosures.

This advantage is particularly advantageous when system 100 is utilized in a server enclosure, such as within a server tray or server blade. The data storage industry judges overall performance in multi-CPU server systems based on the ambient temperature at which any CPU in the system first starts to become stifled or throttled (commonly referred to as “absolute throttle temperature”). As note above, although present invention causes the temperature of front CPU 160 to rise, it significantly reduces the temperature of rear CPU 160. In doing so, the cooling system of the present invention ultimately increases absolute throttle temperature, a fact that translates to increased system reliability in the eyes of customers and end-users.

FIG. 1B is a top view of an exemplary system for cooling multiple in-line CPUs without a radiator in a confined enclosure in accordance with the present invention. The system of FIG. 1B includes similar elements as that in FIG. 1A. The primary difference is that, in the embodiment illustrated in FIG. 1B, there is no radiator attached to the heat sink. As illustrated in FIG. 1B, a radiator is not required for the present invention.

FIG. 2 is a side view of another exemplary system for cooling multiple in-line CPUs in a confined enclosure in accordance with the present invention. In an embodiment, a system 200 for cooling multiple in-line CPUs in a confined enclosure (not shown) may include a rear CPU 210 and a rear heat sink 220 coupled to rear CPU 210. Rear heat sink 220 may include a plurality of fins 230. Fins 230 of rear heat sink 220 may protrude from rear heat sink 220 to provide added surface area through which rear heat sink 220 may receive air flow 240 and have its heat dissipated.

A front CPU 250 may be disposed in line with rear CPU 210 and coupled to a front heat sink 260. Front heat sink 260 may include a plurality of fins 270. Fins 270 of front heat sink 260 may protrude from front heat sink 260 to provide added surface area through which front heat sink 260 may contact air flow 240 and have its heat dissipated. Either rear heat sink 220 or front heat sink 260 may be a standard aluminum heat sink, a vapor chamber heat sink, a forged heat sink, a swaged heat sink, a skived heat sink, an extruded heat sink, a stamped heat sink, a bonded fin heat sink, a folded fin heat sink, or any other heat sink known in the art. Either rear heat sink 220 or front heat sink 260 may be constructed of aluminum, copper, or any other suitable material known in the art.

The system may include one or more heat pipes 275. Each heat pipe 275 may have a longitudinal body 280 bounded by an inlet 285 and an outlet 290. Each inlet 285 may be coupled to rear heat sink 220 and each outlet 290 may be coupled to front heat sink 260. One or more heat pipes 275 may be constructed of any thermally conductive material known in the art, such as copper, aluminum, gold, or silver with appropriate wick and tube construction to allow the heat pipe to function as a heat pipe. Moreover, one or more heat pipes 275 may be any size or shape depending on design considerations, including the size of the enclosure, the arrangements of components within the enclosure, and air flow conditions. One or more heat pipes 275 may be casted, extruded, or manufactured using any other suitable method known in the art.

In operation, because front heat sink 260 is connected to the rear heat sink 220 via one or more heat pipes 275, the extra heat front the rear heat sink 220 can travel through the heat pipe(s) 275 to the cooler front heat sink. One or more heat pipes 275 between the two (or more) heat sinks act to equalize their temperatures between the heat sinks, and therefore, the CPUs. This lowers the temperature of the rear processor and increased the ambient temperature the unit will function at before any processors throttle. As a result, system 200 ultimately dissipates heat from rear CPU 210 more effectively than previously attempted cooling solutions. System 200 may be tuned to determine optimum heat sink and heat pipe types. For example, in one embodiment, front heat and rear heat sink 260 and 220 may be vapor chamber heat sinks coupled by one or more copper heat pipes. In various embodiments, the optimal quantity, size, shape, and material of front heat sink 260, rear heat sink 220, and one or more heat pipes will depend on a number of design variables, including server design, enclosure size, and air flow conditions.

Although system 200 increases the temperature of front CPU 250 by pulling heat from the rear CPU 210, system 200 significantly drops the temperature of rear CPU 210. For example, in one embodiment, the temperature of rear CPU 210 may be reduced as much as 20 degrees Centigrade. In doing so, system 200 effectively equalizes the temperature difference between front CPU 250 and rear CPU 210. As a result, the ambient temperature at which the throttle temperature of system 200 is increased, which ultimately improves overall system performance and reliability.

As noted above, the system effectively cools rear CPU 210 without the use of an external radiator. Accordingly, in various embodiments, front CPU 250, front heat sink 260, rear CPU 210, rear heat sink 220, and one or more heat pipes 275 may be enclosed in an enclosure having insufficient space to house an external radiator. For example, the system may be applied flexibly to a variety of computer systems, such as server trays or server blades. Front CPU 250 and rear CPU 210 may be located almost anywhere in the enclosure—even with large components between them—because one or more heat pipes 275 may be routed around such obstructions. Specifically, in some embodiments, one or more heat pipes 275 may directly couple front heat sink 260 to rear heat sink 220 without extending past any intervening obstructions. In other embodiments, one or more heat pipes 275 may couple front heat sink 260 to rear heat sink 220 while extending past one or more intervening obstructions. Heat pipes 275 may also “zig zag” across front and rear CPUs 250 and 210 to maximize heat transfer.

Although system 200 need not utilize an external radiator, such a radiator 295 may be employed in various embodiments if desired. In such cases, one or more heat pipes 275 may include an additional segment that couples rear heat sink 220 or front heat sink 260, to radiator 295. Radiator 295 may be located near the rear of the enclosure where one or more fans (not shown) may exhaust heat from the enclosure. In various embodiments, whether radiator 295 my be employed will depend on various design considerations, such as enclosure dimensions, the size and shape of the heat sinks and heat pipes, and cost variables.

These features provides a significant advantage over previously attempted cooling systems that are too expensive, too bulky, or too ineffective to adequately cool rear CPU 210 within a confined enclosure. As discussed above, the server industry judges overall performance in multi-CPU server systems based on absolute throttle temperature. Although system 200 increases the temperature of front CPU 250, it reduces the temperature of rear CPU 210 such that the absolute throttle temperature of system 200 is increased. In doing so, system 200 increases overall system performance and reliability.

The foregoing detailed description of the technology herein has been presented for purposes of illustration and description. It is not intended to be exhaustive or to limit the technology to the precise form disclosed. Many modifications and variations are possible in light of the above teaching. The described embodiments were chosen in order to best explain the principles of the technology and its practical application to thereby enable others skilled in the art to best utilize the technology in various embodiments and with various modifications as are suited to the particular use contemplated. It is intended that the scope of the technology be defined by the claims appended hereto.

What is claimed is:

1. A system for cooling multiple in-line CPUs in a confined enclosure, comprising:
a front CPU;
a front heat sink coupled to the front CPU, the front heat sink having a plurality of fins and a corresponding fin pitch;
a rear CPU disposed substantially in line with the front CPU; and
a rear heat sink coupled to the rear CPU, the rear heat sink having a plurality of fins and a corresponding fin pitch, and the fin pitch of the rear heat sink being higher than the fin pitch of the front heat sink.

2. The system of claim 1, wherein the front CPU, the front heat sink, the rear CPU, and the rear heat sink are enclosed in an enclosure having insufficient space to house an external radiator.

3. The system of claim 1, wherein the front heat sink is a vapor chamber heat sink.

4. The system of claim 1, wherein the rear heat sink is a vapor chamber heat sink.

5. The system of claim 1, wherein the front heat sink includes between thirty and thirty-five fins.

6. The system of claim 1, wherein the rear heat sink includes between forty-five and fifty fins.

7. A system for cooling multiple in-line CPUs in a confined enclosure, comprising:
a front CPU;
a front heat sink coupled to the front CPU;
a rear CPU disposed substantially in line with the front CPU;
a rear heat sink coupled to the rear CPU; and
one or more heat pipes, each heat pipe having a longitudinal body bounded by an inlet and an outlet, each inlet coupled to the rear heat sink, and each outlet coupled to the front heat sink.

8. The system of claim 7, wherein the front CPU, the front heat sink, the rear CPU, the rear heat sink, and the one or more heat pipes are enclosed in an enclosure having insufficient space to house an external radiator.

9. The system of claim 7, wherein the one or more heat pipes directly couple the front heat sink to the rear heat sink without extending past any intervening obstructions.

10. The system of claim 7, wherein the one or more heat pipes couple the front heat sink to the rear heat sink while extending past one or more intervening obstructions.

11. The system of claim 7, wherein the front heat sink is a vapor chamber heat sink.

12. The system of claim 7, wherein the rear heat sink is a vapor chamber heat sink.
